(19) United States
(12) Patent Application Publication
(10) Pub. No.: US 2019/0074258 A1
(43) Pub. Date: Mar. 7, 2019

(54) SOLDER PAD, SEMICONDUCTOR CHIP COMPRISING SOLDER PAD, AND FORMING METHOD THEREFOR

(71) Applicant: China Wafer Level CSP Co., Ltd., Suzhou, Jiangsu (CN)

(72) Inventors: Zhiqi Wang, Suzhou, Jiangsu (CN); Xinqin Wang, Suzhou, Jiangsu (CN)

(73) Assignee: China Wafer Level CSP Co., Ltd., Suzhou, Jiangsu (CN)

(21) Appl. No.: 15/767,122

(22) PCT Filed: Oct. 14, 2016
(86) PCT No.: PCT/CN2016/102136

§ 371 Date: Apr. 9, 2018

(30) Foreign Application Priority Data
Dec. 29, 2015 (CN) 201511009450.8
Dec. 29, 2015 (CN) 201521116234.9

(51) Int. Cl. H01L 23/00; H01L 21/768

(52) U.S. Cl. CPC H01L 24/08; H01L 21/76897; H01L 21/76843; H01L 24/03

(57) ABSTRACT

A solder pad, a semiconductor chip including the solder pad, and a forming method therefor are provided. A solder pad includes at least two metal layers and a dielectric layer located between adjacent metal layers. The solder pad includes a laser drilling region; the dielectric layer is provided with an opening corresponding to the laser drilling region; a metal plug is provided in the opening, both ends of the metal plug being respectively in contact with the adjacent metal layers. A method for forming a solder pad improves the quality of laser drilling performed on a solder pad and reduces the difficulty of the laser drilling; laser acts on a metal substance without being in contact with a dielectric layer, so as to effectively prevent a dielectric layer from heat distortion.

The present application claims priority to Chinese Patent Application No. 201511009450.8, titled “SEMICONDUCTOR CHIP AND FORMING METHOD THEREFOR”, filed on Dec. 29, 2015 with the State Intellectual Property Office of People's Republic of China, and Chinese Patent Application No. 201521116234.9, titled “SEMICONDUCTOR CHIP”, filed on Dec. 29, 2015 with the State Intellectual Property Office of People's Republic of China, both of which are incorporated herein by reference in their entireties.

### FIELD

The present disclosure relates to the technical field of semiconductor chips, and in particular to the field of semiconductor chip manufacturing

### BACKGROUND

Laser drilling technology is widely used in the field of semiconductors, especially in the field of semiconductor chip packaging.

Reference is made to FIG. 1 and FIG. 2, where FIG. 1 is a schematic structural diagram of a wafer-level semiconductor chip, and FIG. 2 is a schematic structural diagram of a package of a semiconductor chip. Referring to FIG. 1, a wafer 100 includes multiple semiconductor chips 201 arranged in an array. A cutting trench region is provided between adjacent semiconductor chips 201. After the wafer level packaging and testing are completed, the semiconductor chips 201 are separated from each other along the cutting trench regions. Each of the semiconductor chips 201 includes an integrated circuit and multiple contact pads electrically connected to the integrated circuit. The contact pad is configured to electrically connect with an external circuit.

Referring to FIG. 2, an image sensing chip is taken as an example. A protection layer 203 is arranged on a first surface I of the semiconductor chip 201. Contact pads 202 are located in the protection layer 203. An optical device layer 207 is arranged in a position in the protection layer 203 corresponding to a photosensitive region. A partition wall 205 is arranged on a protection substrate 200. After the semiconductor chip 201 is laminated with the protection substrate 200 in an alignment manner, the optical device layer 207 is located in a cavity 206 formed by surrounding by the partition wall 205.

In the structure shown in FIG. 2, in order to electrically connect the contact pad 202 and the external circuit, a laser hole 209 penetrating the contact pad 202 is formed on the contact pad 202 and a metal wiring layer 210 extending to a second surface II of the semiconductor chip 201 is formed in the laser hole 209, then a solder ball 212 connected to the metal wiring layer 210 is formed on the second surface II. The contact pad 202 is electrically connected to the external circuit through the solder ball 212. In addition, in order to prevent mutual interference between the metal wiring layer 210 and other circuits in the semiconductor chip 201, an insulating layer 208a and an insulating layer 211 are formed on the semiconductor chip 201 to isolate the metal wiring layer from the other circuits.

In the conventional technology, the contact pad generally has a multi-layer structure, i.e., including at least two metal layers and a dielectric layer between adjacent metal layers. The structure and the material of the contact pad directly affect the quality and difficulty of laser drilling. Therefore, a technical issue to be solved by those skilled in the art is how to improve the quality of the laser drilling for the contact pad and reduce the difficulty of the laser drilling.

### SUMMARY

A contact pad with a new structure is designed according to the disclosure, which improves a quality of laser drilling for the contact pad and reduces difficulty of the laser drilling.

In an aspect of the present disclosure, a contact pad is provided, where the contact pad includes at least two metal layers and a dielectric layer located between adjacent metal layers. A laser drilling region is arranged on the contact pad, an opening is arranged in a position in the dielectric layer corresponding to the laser drilling region, a metal plug is arranged in the opening, and both ends of the metal plug are in contact with adjacent metal layers, respectively.

Optionally, the metal plug includes: a barrier layer formed on a bottom of the opening in contact with the metal layer and a sidewall of the opening; a diffusion barrier layer located on the barrier layer; and a filler metal located on the diffusion barrier layer and filling the opening.

Optionally, the filler metal is made of tungsten, the barrier layer is made of titanium, and the diffusion barrier layer is made of titanium nitride.

Optionally, at least one opening is further arranged in a region other than a position of the opening in the dielectric layer to form a conductive plug in the at least one opening, and both ends of the conductive plug are electrically connected to adjacent metal layers, respectively.

Optionally, the conductive plug and the metal plug are made of a same material and have a same structure.

Optionally, the metal layer includes a barrier layer tightly integrated with a protection layer or the dielectric layer of the contact pad, an intermediate metal layer bonded with the barrier layer, and an anti-reflection layer deposited on the intermediate metal layer.

Optionally, the barrier layer is made of titanium, the intermediate metal layer is made of aluminum-copper alloy, and the anti-reflection layer is made of titanium nitride.

Optionally, a laser hole is arranged in the laser drilling region, and the laser hole penetrates the metal layer and the metal plug sequentially.

In another aspect of the present disclosure, a semiconductor chip including the above-described contact pad is provided.

In another aspect of the present disclosure, a method for forming a contact pad of a semiconductor chip is provided, which includes: (a) forming a metal layer; (b) forming a dielectric layer on the metal layer; (c) forming a metal plug in the dielectric layer, where the metal plug is located in a laser drilling region; and (d) forming another metal layer on the dielectric layer.

Optionally, the step of forming the metal plug in the dielectric layer includes: forming an opening on the dielectric layer with an etching process; forming a barrier layer on a bottom of the opening and a sidewall of the opening with a deposition process; forming a diffusion barrier layer on the barrier layer with the deposition process; and forming a filler metal filling the opening on the diffusion barrier layer with the deposition process.

Optionally, the filler metal is made of tungsten, the barrier layer is made of titanium, and the diffusion barrier layer is made of titanium nitride.

Optionally, the method further includes: arranging at least one opening in a region other than a position of the opening to form a conductive plug in the at least one opening, where both ends of the conductive plug are electrically connected to adjacent metal layers, respectively.

Optionally, the conductive plug and the metal plug are formed with a same material and method.

Optionally, the step of forming the metal layer includes: depositing a barrier layer on a protection layer or the dielectric layer of the contact pad with a deposition process; depositing an intermediate metal layer on the barrier layer with the deposition process; depositing an anti-reflection layer on the intermediate metal layer with the deposition process; and forming a metal layer having a same shape as that of the contact pad by imprinting a silicon wafer using photoresist and performing an etching process.

Optionally, the barrier layer is made of titanium, the intermediate metal layer is made of aluminum-copper alloy, and the anti-reflection layer is made of titanium nitride.

Optionally, a laser hole sequentially penetrating the metal layer and the metal plug is formed in the laser drilling region of the contact pad.

Optionally, steps (b) to (d) are performed repeatedly to form multiple metal layers and dielectric layers. Beneficial effects of the disclosure are that: the quality of the laser drilling for the contact pad is improved and the difficulty of laser drilling is reduced. The laser acts on the metal material and is prevented from contacting with the dielectric layer, and thus thermal deformation of the dielectric layer can be effectively prevented and an inner wall of the laser hole can be prevented from cracking. In addition, since a whole sidewall of the laser hole is made of metal, electrical conductivity of the contact pad is improved.

### BRIEF DESCRIPTION OF THE DRAWINGS

FIG. 1 is a schematic structural diagram of a wafer according to the conventional technology.

FIG. 2 is a schematic diagram of a package of an image sensing chip according to the conventional technology.

FIG. 3A is a schematic structural diagram of a semiconductor chip according to a preferred embodiment of the present disclosure.

FIG. 3B is a cross-sectional view of a semiconductor chip according to a preferred embodiment of the present disclosure.

FIG. 4 is a cross-sectional view of a contact pad according to a preferred embodiment of the present disclosure.

FIG. 5 is a schematic structural diagram of a metal layer according to a preferred embodiment of the present disclosure.

FIG. 6 is a schematic structural diagram of a metal plug arranged in a dielectric layer according to a preferred embodiment of the present disclosure.

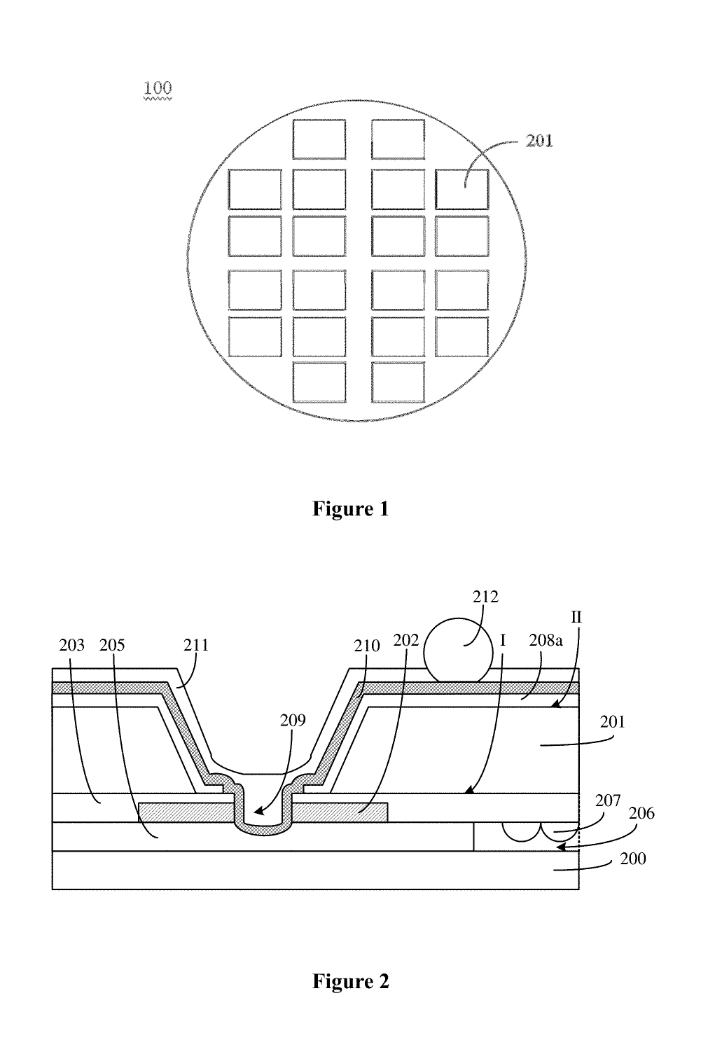

### DETAILED DESCRIPTION OF EMBODIMENTS

The specific embodiments of the present disclosure are described in detail below with reference to the accompanying drawings. However, the embodiments are not intended to limit the present disclosure. Any modifications to structures, methods or functions made by those skilled in the art based on these embodiments fall within the protection scope of the present disclosure.

It should be noted that these drawings are provided for the purpose of facilitating understanding of the embodiments of the present disclosure and should not be construed as limiting the present disclosure. For the sake of clarity, the dimensions shown in the figures are not drawn to scale and may be enlarged, reduced, or altered in other manner.

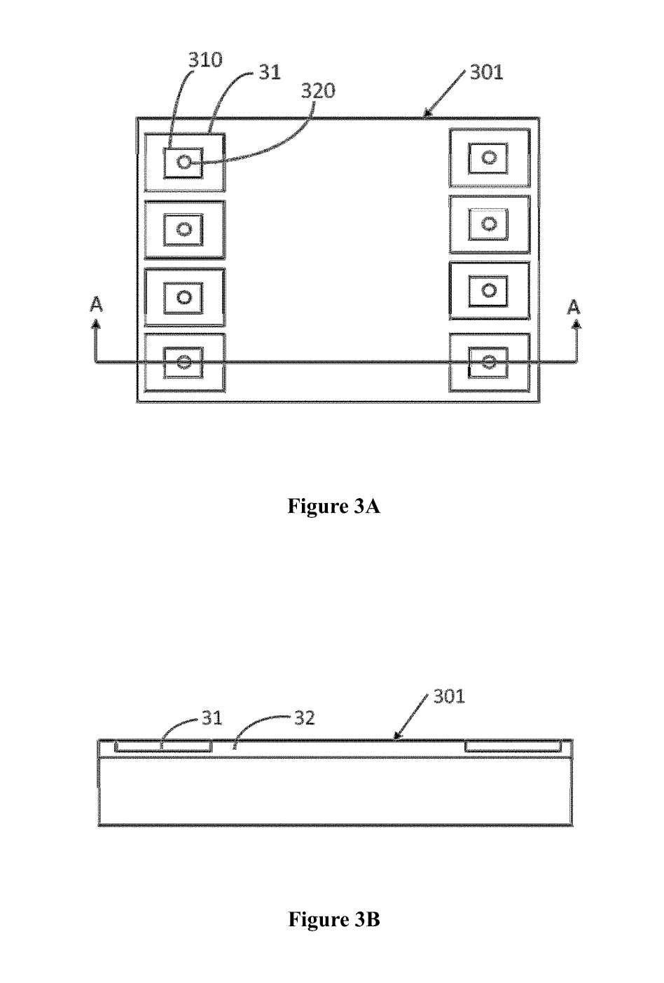

Referring to FIG. 3A and FIG. 3B, a semiconductor chip 301 includes an integrated circuit (not shown in FIG. 3A) and multiple contact pads 31 electrically connected to the integrated circuit. The contact pad 31 is configured to electrically connect with an external circuit. A structure and a function of the integrated circuit are not limited in the present disclosure, and the integrated circuit is broadly explained herein. That is, the so-called integrated circuit is a circuit having some functions and formed by integrating a number of commonly used electronic elements such as a resistor, a capacitor, a transistor and connection lines between the electronic elements with a semiconductor process. A protection layer 32 is arranged on a surface of the semiconductor chip 301, and the contact pad 31 is arranged in the protection layer 32.

A laser drilling region 310 is arranged on the contact pad 31, and in a subsequent process of the laser drilling, a laser hole 320 is arranged in the laser drilling region and an area of the laser drilling region is greater than an area of the laser hole. In order to simplify the laser drilling operation and facilitate positioning the laser hole to the laser drilling region, the laser drilling region is arranged at a center of the contact pad 31. In this way, the laser drilling operation is performed only by aligning a laser beam with the center of the contact pad 31 without additionally providing a laser alignment mark.

In this embodiment, a shape of the laser drilling region 310 is square. The shape of the laser drilling region 310 is not limited in the present disclosure, and the shape of the laser drilling region 310 may be circular, as long as the laser hole is located in the laser drilling region and there is a spacing between a sidewall of the laser hole and a side edge of the laser drilling region 310.

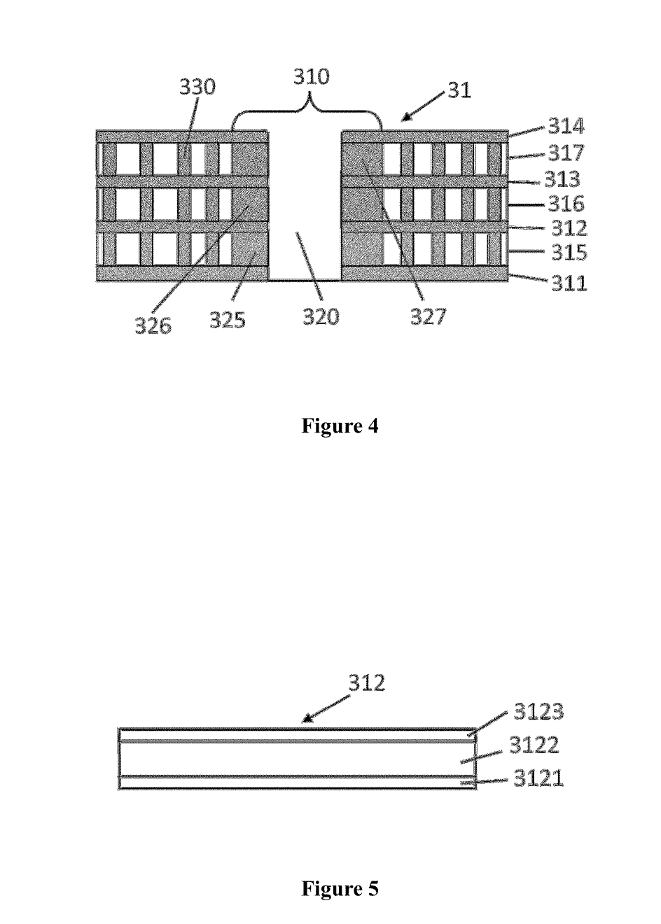

FIG. 4 is a cross-sectional view of the contact pad 31. In this embodiment, the contact pad 31 includes four metal layers, that is, a first metal layer 311, a second metal layer 312, a third metal layer 313, and a fourth metal layer 314. A first dielectric layer 315 is provided between the first metal layer 311 and the second metal layer 312, a second dielectric layer 316 is provided between the second metal layer 312 and the third metal layer 313, and a third dielectric layer 317 is provided between the third metal layer 313 and the fourth metal layer 314.

An opening is arranged in a position in each of the dielectric layers corresponding to the laser drilling region 310, and a metal plug is arranged in the opening. In FIG. 4, a first metal plug 325, a second metal plug 326 and a third metal plug 327 are arranged in the openings of the dielectric layers. Both ends of each metal plug are in contact with adjacent metal layers respectively, that is, both ends of the first metal plug 325 are in contact with the first metal layer 311 and the second metal layer 312 respectively, both ends of the second metal plug 326 are in contact with the second metal layer 312 and the third metal layer 313 respectively, and both ends of the third metal plug 327 are in contact with the third metal layer 313 and the fourth metal layer 314 respectively.

In a subsequent process of the laser drilling, a laser hole 320 penetrating the contact pad 31 is formed in the laser drilling region 310 of the contact pad 31. In FIG. 4, the laser hole 320 penetrates the fourth metal layer 314, the third metal plug 327, the third metal layer 313, the second metal plug 326, the second metal layer 312, the first metal plug 325, and the first metal layer 311, sequentially.

In order to improve stability of an electrical connection between metal layers, at least one opening is further arranged in a region other than positions of the openings in the dielectric layers to provide a conductive plug 330 in the at least one opening. Both ends of the conductive plug 330 are electrically connected to adjacent metal layers, respectively.

In order to improve simplicity and convenience of the process, the metal plug and the conductive plug can be fabricated simultaneously.

The contact pad 31 is formed in a wafer level process.

First, a first metal layer 311 is formed, and a first dielectric layer 315 is formed on the first metal layer 311. Second, a first metal plug 325 and at least one conductive plug 330 are formed in the first dielectric layer 315. Then, a second metal layer 312 is formed on the first dielectric layer 315. The above steps are performed repeatedly and finally a structure of a contact pad as shown in FIG. 4 is formed.

The metal layer has a multi-layer structure. Referring to FIG. 5, the second metal layer 312 is taken as an example, and a process of fabricating the second metal layer 312 includes the following four steps:

(1) depositing a barrier layer 3121 on the first dielectric layer 315, where the barrier layer 3121 is made of titanium, and the barrier layer 3121 is tightly integrated with the first dielectric layer 315;

(2) depositing an intermediate metal layer 3122 on the barrier layer 3121, where the intermediate metal layer 3122 is made of aluminum-copper alloy, and the barrier layer 3121 is bonded well with the intermediate metal layer;

(3) depositing an anti-reflection layer 3123 on the aluminum-copper alloy layer 3112, where the anti-reflection layer 3123 is made of titanium nitride, and the anti-reflection layer 3123 may serve as an anti-reflection layer in the etching process; and

(4) forming the second metal layer 312 having the same shape as that of the contact pad by imprinting a silicon wafer by using photoresist and performing the etching process.

For the first metal layer 311, a barrier layer is deposited on a protection layer 32 of the contact pad.

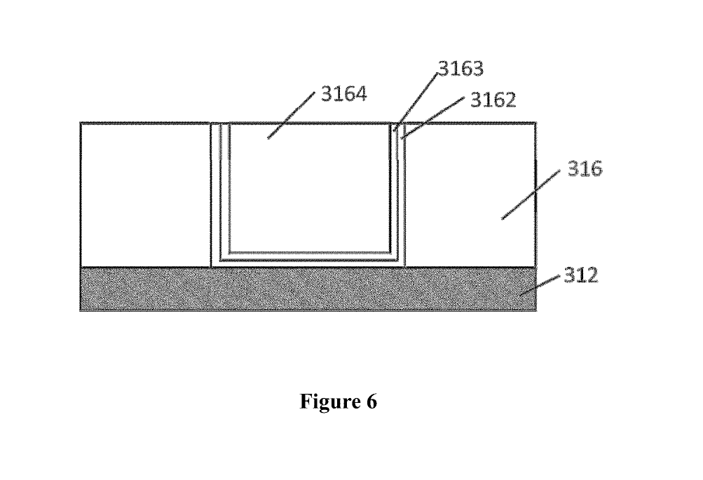

Referring to FIG. 6, the second metal plug 326 is taken as an example, and a process of fabricating the second metal plug 326 includes the following six steps:

(1) forming a second dielectric layer 316 on the second metal layer 312 after the second metal layer 312 is fabricated, where the second dielectric layer 316 may be made of silicon oxide or silicon nitride;

(2) forming an opening in the dielectric layer 316 by etching the second dielectric layer 316, where the second metal layer 312 is exposed through the bottom of the opening;

(3) depositing a barrier layer 3162 on the bottom and a sidewall of the opening, where the barrier layer 3162 is made of titanium;

(4) depositing a diffusion barrier layer 3163 on the barrier layer 3162, where the diffusion barrier layer is made of titanium nitride;

(5) depositing, in the opening, a filler metal 3164 filling the opening; in this embodiment, the filler metal 3164 is made of tungsten which can fill the opening without any void and has good grinding and polishing properties, the barrier layer 3162 serves as adhesive between the filler metal 3164 and the second dielectric layer 316, and the diffusion barrier layer 3163 is used to block diffusion of the filler metal 3164; and

(6) grinding and polishing the filler metal 3164 to make a height of the filler metal 3164 flush with the surface of the second dielectric layer 316.

The process of fabricating the conductive plug 330 is the same as the process of fabricating the second metal plug 326 and is not described herein again.

Based on the special design of the structure of the laser drilling region 310 in the present disclosure, the quality of the laser drilling for the contact pad is improved and the difficulty of the laser drilling is reduced. The laser acts on the metal material and is prevented from contacting with the dielectric layer, thermal deformation of the dielectric layer can be effectively prevented and an inner wall of the laser hole can be prevented from cracking. In addition, since the whole sidewall of the laser hole is made of metal, the electrical conductivity of the contact pad is improved.

It should be understood that although the specification is described according to the embodiments, not each of the embodiments includes only one independent technical solution. The description of the specification is merely for the sake of clarity and those skilled in the art should take the specification as a whole, and the technical solutions in the embodiments may also be appropriately combined to form other embodiments that can be understood by those skilled in the art.

The series of detailed descriptions set forth above only describe the feasible embodiments of the present disclosure and are not intended to limit the protection scope of the present disclosure. Any equivalent embodiment or modification made without departing from the technical spirit of the present disclosure should fall within the protection scope of the present disclosure.

1. A contact pad, comprising:
at least two metal layers; and
a dielectric layer located between adjacent metal layers,
wherein a laser drilling region is arranged on the contact pad, an opening is arranged in a position in the dielectric layer corresponding to the laser drilling region, a metal plug is arranged in the opening, and both ends of the metal plug are in contact with adjacent metal layers, respectively.

2. The contact pad according to claim 1, wherein the metal plug comprises:
a barrier layer formed on a bottom of the opening in contact with the metal layer and a sidewall of the opening;
a diffusion barrier layer located on the barrier layer; and
a filler metal located on the diffusion barrier layer and filling the opening.

3. The contact pad according to claim 2, wherein the filler metal is made of tungsten, the barrier layer is made of titanium, and the diffusion barrier layer is made of titanium nitride.

4. The contact pad according to claim 3, wherein at least one opening is further arranged in a region other than a position of the opening in the dielectric layer to form a conductive plug in the at least one opening, and both ends of the conductive plug are electrically connected to adjacent metal layers, respectively.

5. The contact pad according to claim 4, wherein the conductive plug and the metal plug are made of a same material and have a same structure.

6. The contact pad according to claim 1, wherein the metal layer comprises a barrier layer tightly integrated with a protection layer or the dielectric layer of the contact pad, an intermediate metal layer bonded with the barrier layer, and an anti-reflection layer deposited on the intermediate metal layer.

7. The contact pad according to claim 6, wherein the barrier layer is made of titanium, the intermediate metal layer is made of aluminum-copper alloy, and the anti-reflection layer is made of titanium nitride.

8. The contact pad according to claim 1, wherein a laser hole is arranged in the laser drilling region, and the laser hole penetrates the metal layer and the metal plug sequentially.

9. A semiconductor chip comprising the contact pad according to claim 1.

10. A method for forming a contact pad of a semiconductor chip, comprising:
(a) forming a metal layer;
(b) forming a dielectric layer on the metal layer;
(c) forming a metal plug in the dielectric layer, wherein the metal plug is located in a laser drilling region; and
(d) forming another metal layer on the dielectric layer.

11. The method for forming the contact pad according to claim 10, wherein the forming the metal plug in the dielectric layer comprises:
forming an opening on the dielectric layer with an etching process;
forming a barrier layer on a bottom of the opening and a sidewall of the opening with a deposition process;
forming a diffusion barrier layer on the barrier layer with the deposition process; and
forming a filler metal filling the opening on the diffusion barrier layer with the deposition process.

12. The method for forming the contact pad according to claim 11, wherein the filler metal is made of tungsten, the barrier layer is made of titanium, and the diffusion barrier layer is made of titanium nitride.

13. The method for forming the contact pad according to claim 12, further comprising:
arranging at least one opening in a region other than a position of the opening to form a conductive plug in the at least one opening, wherein both ends of the conductive plug are electrically connected to adjacent metal layers, respectively.

14. The method for forming the contact pad according to claim 13, wherein the conductive plug and the metal plug are formed with a same material and method.

15. The method for forming the contact pad according to claim 10, wherein the forming the metal layer comprises:
depositing a barrier layer on a protection layer or the dielectric layer of the contact pad with a deposition process;
depositing an intermediate metal layer on the barrier layer with the deposition process;
depositing an anti-reflection layer on the intermediate metal layer with the deposition process; and
forming a metal layer having a same shape as that of the contact pad by imprinting a silicon wafer using photoresist and performing an etching process.

16. The method for forming the contact pad according to claim 15, wherein the barrier layer is made of titanium, the intermediate metal layer is made of aluminum-copper alloy, and the anti-reflection layer is made of titanium nitride.

17. The method for forming the contact pad according to claim 10, wherein a laser hole sequentially penetrating the metal layer and the metal plug is formed in the laser drilling region of the contact pad.

18. The method for forming the contact pad according to claim 10, wherein steps (b) to (d) are performed repeatedly to form a plurality of metal layers and dielectric layers.

19. A semiconductor chip comprising the contact pad according to claim 2.

20. A semiconductor chip comprising the contact pad according to claim 3.
